(19) United States
(12) Patent Application Publication
(10) Pub. No.: US 2016/0211644 A1
(43) Pub. Date: Jul. 21, 2016

(54) EDGE-EMITTING LASER CHIP WAFER LAYOUT THAT FACILITATES ON-WAFER TESTING OF THE LASERS

(71) Applicant: Avago Technologies General IP (Singapore) Pte. Ltd, Singapore (SG)

(72) Inventors: Elaine R. Kleinfeld, Macungie, PA (US); Yufei Gao, Blue Bell, PA (US); John J. Leiby, Wyomissing, PA (US); James R. Lothian, Bethlehem, PA (US)

(21) Appl. No.: 14/599,627

(22) Filed: Jan. 19, 2015

(51) Int. Cl. H01S 5/00; G01J 1/42; G01J 3/28; H01S 5/40

(52) U.S. Cl. CPC H01S 5/0014; H01S 5/4056; G01J 1/4257; G01J 3/28

(57) ABSTRACT

Edge-emitting laser chip wafer layouts are provided that enable a variety of tests to be performed while the chips are on the wafer, including side-mode suppression ratio (SMSR) tests. The laser chip wafer layouts include turning mirrors that direct light passing out of at least one of the facets of the chips away from the wafer. Directing the light out of the wafer in this manner allows external test and measurement equipment to perform SMSR testing on the chips prior to singulation.

### TECHNICAL FIELD OF THE INVENTION

The invention relates to laser diode manufacturing and testing. More particularly, the invention relates to a wafer layout of edge-emitting laser chips that facilitates on-wafer testing, including testing for side-mode suppression ratio.

### BACKGROUND OF THE INVENTION

Optoelectronic lasers are integrated semiconductor devices that emit light of a particular wavelength or wavelength range when driven by an electrical signal. Optoelectronic lasers come in a wide variety of types and are used in a wide variety of applications. Known optoelectronic laser types include vertical cavity surface emitting lasers (VCSELs) and edge-emitting lasers (e.g., etched-facet lasers, Fabry-Perot lasers, distributed feedback (DFB) lasers, electroabsorbtive-modulated lasers (EML), and distributed Bragg reflector (DBR) lasers). VCSELs and edge-emitting lasers are made using a wide variety of semiconductor fabrication processes. In general, the semiconductor fabrication processes all involve forming a large number of laser chips on a wafer, dicing the wafer into individual laser chips, and then packaging the individual laser chips.

Prior to dicing the wafers, on-wafer testing can be performed to determine whether the lasers meet certain performance criteria. This testing is typically accomplished by injecting electrical current into the lasers and measuring characteristics of the emitted light, such as optical power and wavelength. VCSELs emit light in a direction perpendicular to the plane of the wafer whereas edge-emitting lasers emit light within the wafer in directions that are parallel to the plane of the wafer. VCSELs are tested by using an optical detector that is external to the wafer to detect the light emitted perpendicular to the wafer. Test and measurement equipment processes the electrical signal output from the optical detector to determine characteristics of the emitted light from the VCSEL, including optical power, wavelength, and side-mode suppression ratio (SMSR).

Because edge-emitting lasers emit light within the plane of the wafer, they cannot be fully tested on the wafer. On-wafer testing of edge-emitting lasers can be performed to determine optical power and wavelength, but it is not currently possible to perform on-wafer SMSR testing of edge-emitting lasers. The ability to test VCSELs on the wafer not only for wavelength and optical power, but also for SMSR is a key advantage of VCSELs over edge-emitting lasers.

FIG. 1 illustrates a top plan view of a known layout of a wafer 1 having a plurality of edge-emitting laser chips 2. FIG. 2 illustrates a side cross-sectional view of the portion of the layout shown in FIG. 1 taken along line A-A′. For illustrative purposes, nine edge-emitting laser chips 2 are shown in FIG. 1 although a typical wafer contains anywhere from hundreds to tens of thousands of such chips. In the top plan view of FIG. 1, only portions 3a-3c of a metal contact layer 3 and first and second etched facets 6 and 7 of each chip 2 are visible. Other portions of the laser diode chips 2, such as the active regions 5 (FIG. 2), are underneath the metal contact layer 3. The first and second etched facets 6 and 7 are formed at opposite ends of the respective active regions 5. The first and second etched facets 6 and 7 are pits defined by vertical side walls, i.e., walls perpendicular to the plane of the wafer surface 1a, and flat bottoms, i.e., a surface that is parallel to the plane of the wafer surface 1a. The first and second etched facets 6 and 7 are typically coated with anti-reflection (AR) coatings. The active regions 5 (FIG. 2) of the chips 2 convert electrical current into light, which is then emitted from the etched facets 6 and 7 of the chips 2 in a plane that is parallel to the drawing sheet containing FIG. 1.

The manner in which on-wafer testing of edge-emitting lasers is currently performed will now be described with reference to FIG. 2. The center chip 2a represents the device under test (DUT) in this example and the neighboring chips 2b and 2c are operated as optical detectors to measure the light emitted by the center chip 2a through etched facets 6a and 7a of the center chip 2a. The dashed arrow 11 represents light emitted by the active region 5 of the center chip 2a. The light emitted by the active region 5 of chip 2a propagates toward the etched facets 6a and 7a, respectively. A portion of the light that passes out of etched facet 6a then passes through etched facet 7b of chip 2b. Chip 2b, being operated as an optical detector, converts the light received in chip 2b into an electrical current signal, which is then measured by test and measurement equipment (not shown) external to the wafer 1. Based on this measurement, the test and measurement equipment determines the optical power of the chip 2a. Chip 2c may be operated in the same manner to measure the optical power of chip 2a.

Smaller portions of the light from chip 2a that is incident on the etched facets 7b and 6c of chips 2b and 2c, respectively, are scattered out of the wafer 1. The dashed arrows 12 represent the portions of the light that are scattered out of the wafer 1. Test and measurement equipment (not shown) external to the wafer 1 includes an optical detector that detects this scattered light 12 and determines the wavelength of the detected light.

While the intensity of this scattered light 12 is sufficient to measure the wavelength of the light emitted by chip 2a, it is insufficient to measure the SMSR of the chip 2a. For this reason, if SMSR measurements are made at all, they are made after the wafer 1 has been diced along the chip boundaries represented by dashed lines 13 and along streets represented by dashed lines 14 (FIG. 1) into individual chips 2. Performing the SMSR measurements on the individual chips 2 involves more handling of the chips 2 and is a time-consuming process that increases the overall manufacturing costs. In some cases, SMSR testing is simply not performed. In such cases, the chips typically are provided with AR/AR coatings and specialized gratings that ensure that SMSR is satisfactory in most cases. However, chips that include these features inherently have low optical power, and therefore are limited to use in applications that can tolerate low optical power.

A need exists for an edge-emitting laser chip wafer layout that allows a sufficient amount of light to be directed out of the plane of the wafer to enable on-wafer SMSR testing to be performed, thereby obviating the need for the AR/AR coating and specialized grating and extending the use of edge-emitting laser technology to packages that require higher optical power.

### SUMMARY OF THE INVENTION

The invention is directed to edge-emitting laser chip wafer layouts and methods. In accordance with an embodiment, the layout of a semiconductor wafer comprises a plurality of edge-emitting laser chips and a plurality of turning mirrors. Each of the chips has a respective edge-emitting laser that emits laser light from at least one facet formed in an edge of the chip. Each turning mirror receives laser light emitted from one of the chips and turns the received laser light away from the wafer at a non-zero-degree angle relative to a plane in which one of the upper and lower surfaces of the wafer lies.

In accordance with another embodiment, the semiconductor wafer comprises a plurality of edge-emitting laser chips, each of which shares a boundary on the wafer with at least one adjacent edge-emitting laser chip, and a plurality of turning mirrors. Each chip has an optical axis. At least a portion of the laser light produced by the laser of each respective chip travels along the respective optical axis of the chip and is emitted from the chip through a first facet of the chip. Each turning mirror is positioned and angled to receive the respective portion of the laser light passing through the first facet of the respective chip and to turn the received laser light by a predetermined turning angle relative to a plane in which one of the upper and lower surfaces of the wafer lies in a direction away from the wafer.

In accordance with an embodiment, a method is provided for measuring characteristics of laser light emitted by edge-emitting laser chips of a semiconductor wafer. The method comprises the following: with turning mirrors positioned on the wafer to receive at least portions of the laser light emitted by edge-emitting lasers of the chips through facets formed in edges of the chips, turning the portions of the laser light emitted by the chips away from the wafer at a non-zero-degree angle to a plane in which one of the upper and lower surfaces of the wafer lies; and, with a first measurement device, measuring at least one of the turned portions of the laser light and determining one or more characteristics of the measured laser light.

In accordance with an embodiment, a method of forming a plurality of turning mirrors on a semiconductor wafer is provided. The method comprises: forming a plurality of turning mirrors on the wafer, with each turning mirror being formed at a position on the wafer that allows the turning mirror to receive laser light emitted by one of the chips. Each turning mirror has a reflecting surface that is at a predetermined angle relative to an optical axis of the respective chip for turning received laser light away from the wafer at a non-zero-degree angle relative to a plane in which one of the upper and lower surfaces of the wafer lies.

These and other features and advantages of the invention will become apparent from the following description, drawings and claims.

### BRIEF DESCRIPTION OF THE DRAWINGS

FIG. 1 illustrates a top plan view of a known layout of a wafer having a plurality of edge-emitting laser chips.

FIG. 2 illustrates a side cross-sectional view of the portion of the layout shown in FIG. 1 taken along line A-A′.

FIG. 3 illustrates a top plan view of a layout of a wafer in accordance with an embodiment that allows edge-emitting laser chips to be SMSR tested while the chips are on the wafer.

FIG. 4 illustrates a side cross-sectional view of the portion of the layout shown in FIG. 3 taken along line B-B′.

FIG. 5 illustrates a top plan view of a layout of a wafer in accordance with another illustrative embodiment.

FIG. 6 illustrates a side cross-sectional view of the portion of the layout shown in FIG. 5 taken along dashed line C-C′.

FIG. 7A illustrates a cross-sectional perspective view of a portion of a semiconductor wafer having an etched facet pit formed therein.

FIG. 7B illustrates a cross-sectional perspective view of the portion of the semiconductor wafer shown in FIG. 7A after a layer of polymer material has been deposited on top of the semiconductor layers.

FIG. 7C illustrates a cross-sectional perspective view of the portion of the semiconductor wafer shown in FIG. 7B after a layer of photoresist has been formed on top of the layer of polymer material.

FIG. 7D illustrates a cross-sectional perspective view of the portion of the semiconductor wafer shown in FIG. 7C after (1) the layer of photoresist has been applied and baked using a standard bake temperature and time period; (2) the layer of photoresist has been patterned into a desired mask via a photolithographic process and (3) the patterned layer of photoresist and the layer of polymer material have been developed using a desired developer agent that will dissolve both the photoresist and the polymer material.

FIG. 7E illustrates a cross-sectional perspective view of the portion of the semiconductor wafer shown in FIG. 7D after a chemical etch process that uses acetone is performed to remove the layer of photoresist.

FIG. 7F illustrates a cross-sectional perspective view of the portion of the semiconductor wafer shown in FIG. 7E after a reflective surface has been formed on the angled surface.

### DETAILED DESCRIPTION OF AN ILLUSTRATIVE EMBODIMENT

Illustrative, or exemplary, embodiments of the invention are directed to edge-emitting laser chip wafer layouts that enable a variety of tests to be performed while the chips are on the wafer, including SMSR tests. The laser chip wafer layouts include turning mirrors that direct light passing out of at least one of the etched facets of the chips out and away from the wafer. Directing the light out and away from the wafer in this manner allows external test and measurement equipment to perform SMSR testing of the chips prior to singulation. Illustrative embodiments of the wafer layouts are described with reference to the figures, in which like reference numerals represent like components, elements or features. For illustrative purposes, the edge-emitting laser chips shown in the drawings and described in the illustrative embodiments are a particular type of edge-emitting laser chip known as an etched-facet laser chip. It should be noted, however, that the invention is not limited to etched-facet laser chips and that the invention is applicable to all types of edge-emitting laser chips. It should also be noted that components, elements or features in the figures are not necessarily drawn to scale, emphasis instead being placed on describing principles and concepts of the invention.

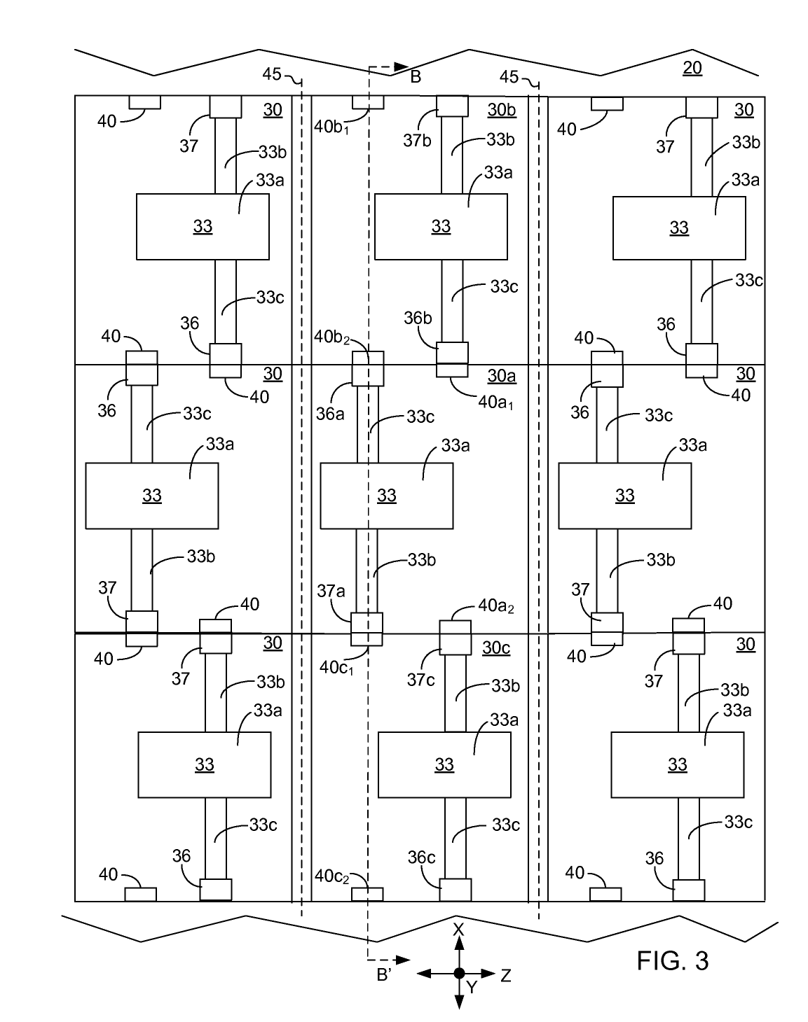

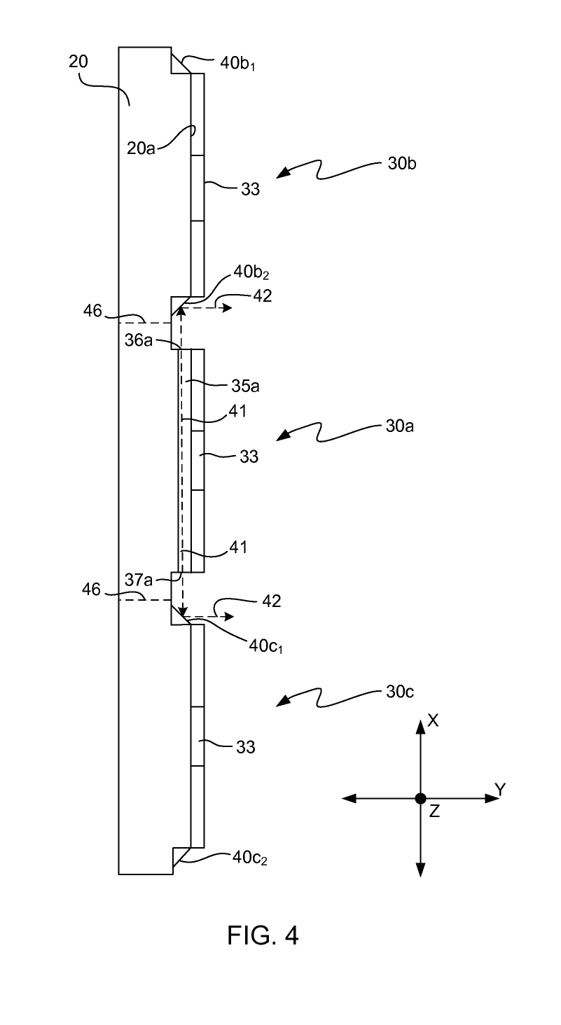

FIG. 3 illustrates a top plan view of a layout of a wafer 20 in accordance with an embodiment that allows edge-emitting laser chips 30 to be SMSR tested while the chips 30 are on the wafer 20. FIG. 4 illustrates a side cross-sectional view of the portion of the layout shown in FIG. 3 taken along line B-B′. For illustrative purposes, nine edge-emitting laser chips 30 are shown in FIG. 3 although, as stated above, a typical wafer contains anywhere from hundreds to tens of thousands of such chips. In the top plan view of FIG. 3, only portions 33a-33c of a metal contact layer 33, turning mirrors 40, and first and second etched facets 36 and 37 of each chip 30 are visible. Other portions of the laser diode chips 30, such as the active regions, are underneath the metal contact layer 33. The first and second etched facets 36 and 37 are formed at opposite ends of the respective active regions 5. The first and second etched facets 36 and 37 are pits defined by substantially vertical side walls (i.e., walls substantially, or nominally, perpendicular to the plane of the wafer surface 20a) and bottom surfaces that interconnect the side walls. It should be noted that although the bottom surfaces of the pits are shown as being flat and perpendicular to the vertical side walls, the bottom surfaces can have other shapes (e.g., curved, arched, rough, concave, convex, etc.). The first and second etched facets 36 and 37 are typically coated with high-reflectivity (HR) and anti-reflectivity (AR) coatings, respectively. The active regions 35 (FIG. 4) of the chips 30 convert electrical current into light, which is then emitted from the etched facets 36 and 37 of the chips 30 in a direction that is parallel to the drawing sheet containing FIG. 4.

In accordance with the illustrative embodiment depicted in FIGS. 3 and 4, the wafer 20 has turning mirrors 40 integrated thereon for reflecting the light that passes through the facets 36 and 37 at a non-zero-degree angle relative to the wafer surface 20a of the wafer 20 assuming the wafer surface 20a is a substantially, or nominally, planar surface that is parallel to an X-Z plane of the X, Y, Z Cartesian Coordinate system shown in FIG. 4. Stated another way, the turning mirrors 40 are positioned and angled to reflect the laser light that passes through the facets 36 and 37 at a non-zero-degree angle relative to the optical axes of the chips 30 along which the laser light is traveling when it passes through the facets 36 and 37 of the respective chips 30. The optical axes are parallel to the X-axis and perpendicular to the Y- and Z-axes of the Cartesian Coordinate system.

In accordance with this embodiment, the non-zero-degree angle is 90°, but the angle could be any angle that is sufficient to allow external detectors to detect the light. Typically, the angle will be selected from a range of about 30° to about 150°. For ease of illustration and discussion, the turning mirrors 40 are shown and will be described as being 45° turning mirrors that reflect light at an angle of 90° relative to the wafer surface 20a. In FIG. 4, the direction of travel of the light before being reflected by the turning mirrors 40 is represented by dashed arrow 41 and the direction of travel of the light after being reflected by the turning mirrors 40 is represented by dashed arrows 42. Dashed arrow 41 also represents the optical axis of the center chip 30a, as it corresponds to the optical pathway along which laser light emitted from the laser of chip 30a travels. It should be noted that while the turning mirrors 40 that oppose facets 36a and 37a are shown reflecting light in the same direction, i.e., parallel to the Y-axis, they could be angled to reflect the received light in different directions.

It can be seen in FIG. 3 that the turning mirrors 40 that are used to reflect the light at the non-zero-degree angle are located on the neighboring chips 30. The etched facet 36 of each chip 30 is adjacent to the turning mirror 40 of the adjacent chip 30. Likewise, the etched facet 37 of each chip 30 is adjacent to the turning mirror 40 of the adjacent chip 30. Because the turning mirror 40 that operates on light from a given chip 30 is on the neighboring chip 30, when the chips 30 are diced, or singulated, from one another, the etched facets 36 and 37 are no longer adjacent to the turning mirrors 40. The turning mirrors 40 remain on the chips 30, but serve no purpose and can be considered throw-away elements.

With reference to FIG. 4, the manner in which the light generated by a given chip 30 is directed out of the wafer 20 at a non-zero-degree angle will now be described with reference to one of the chips 30. The center chip 30a has first and second etched facets 36a and 37a, a metal layer 33, and an active region 35a underneath the metal layer 33. The chip 30b above chip 30a on the drawing page has first and second etched facets (not visible in FIG. 4), a metal layer 33, an active region (not visible in FIG. 4) underneath the metal layer 33, and first and second turning mirrors 40b₁ and 40b₂. The chip 30c below chip 30a on the drawing page has first and second etched facets (not visible in FIG. 4), a metal layer 33, an active region (not visible in FIG. 4) underneath the metal layer 33, and first and second turning mirrors 40c₁ and 40c₂.

For exemplary purposes, it will be assumed that the center chip 30a is the DUT. The light 41 produced by the active region 35a of the center chip 30a travels in a direction that is parallel to the X-axis of the X, Y, Z Cartesian Coordinate system shown in the drawing page. The light 41 passes out of etched facets 36a and 37a and is incident on turning mirrors 40b₂ and 40c₁, respectively. The directions of travel represented by arrow 41 correspond to the optical axis and the optical pathway of the center chip 30a. The turning mirrors 40b₂ and 40c₁, turn, or reflect, the light 41 by an angle of 90°. The reflected light 42 is directed away from the wafer 20 in a direction that is parallel to the Y-axis of the Cartesian Coordinate system and perpendicular to the X- and Z-axes of the Cartesian Coordinate system (i.e., perpendicular to a plane in which the surface 20a of the wafer 20 lies). Optical detectors (not shown) may be positioned external to the wafer 20 to receive and process the reflected light 42 to obtain SMSR measurements. Wavelength and optical power measurements can also be obtained by processing the reflected light.

A variety of other tests may also be performed on the chips 30 prior to the wafer 20 being diced. After the laser chips 30 have been tested, the wafer 20 is diced. The dashed lines 46 in FIG. 4 represent the boundaries along which the wafer 20 is diced. The wafer 20 is also diced in directions perpendicular to the dashed lines 46 along the streets 45 (FIG. 3). As indicated above, after the wafer 20 is diced, each chip 30 has mirrors 40 on it that were used to reflect the light emitted from its neighboring chips 30 on the wafer 20. However, for each singulated chip 30, its mirrors 40 are offset from the etched facets 36 and 37 in the Z-direction (FIG. 3). For example, with reference to center chip 30a in FIG. 3, mirrors 40a₁ and 40a₂ are offset in the Z-direction from the etched facets 36a and 37a, respectively. Therefore, the mirrors 40 that remain on each chip 30 do not detrimentally impact the chip 30 in any way.

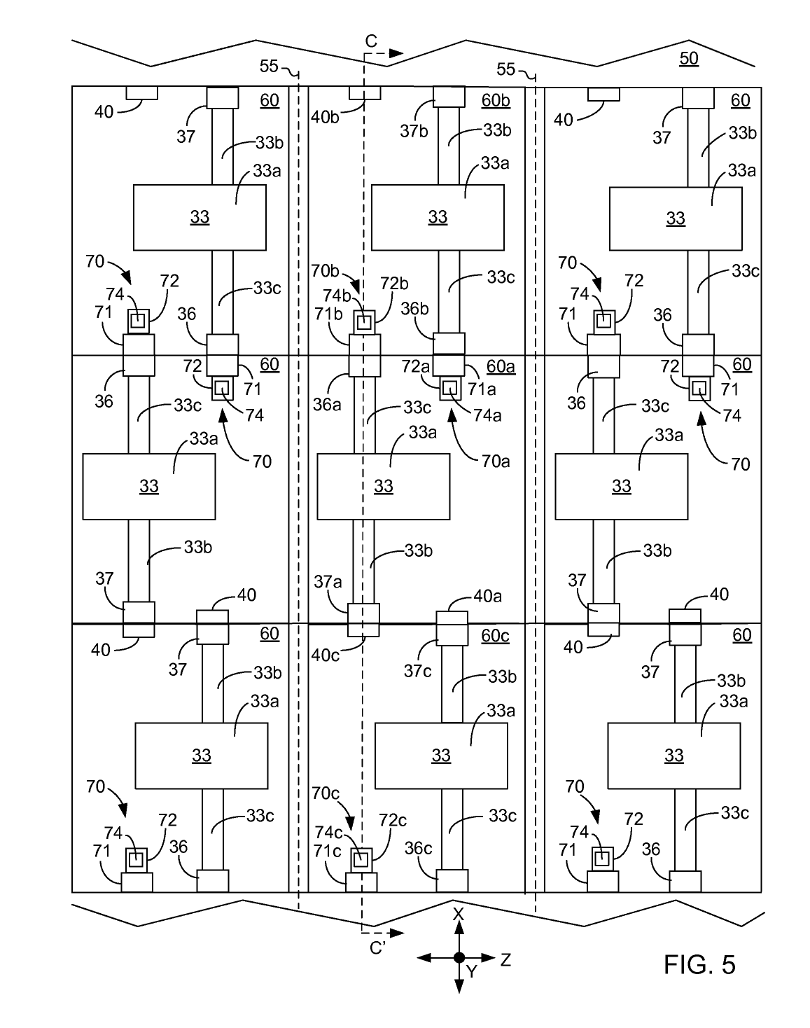

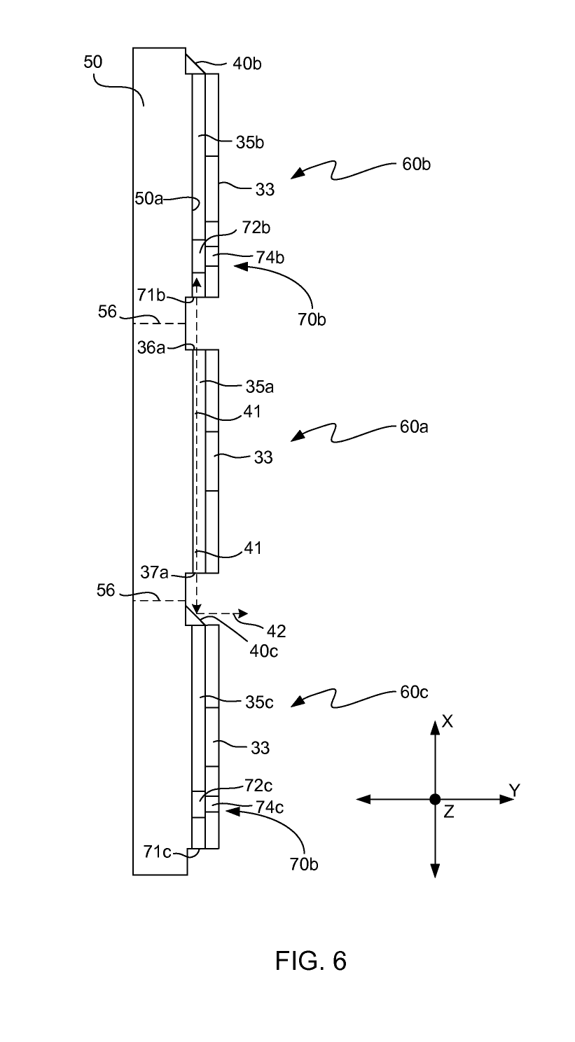

FIG. 5 illustrates a top plan view of a layout of a wafer 50 in accordance with another illustrative embodiment. FIG. 6 illustrates a side cross-sectional view of the portion of the layout shown in FIG. 5 taken along dashed line C-C′. Like the layout shown in FIGS. 3 and 4, the layout shown in FIGS. 5 and 6 allows edge-emitting laser chips to be SMSR tested while the chips are on the wafer. The layout shown in FIG. 5 is similar to the layout shown in FIG. 3 in that the wafer 50 includes the turning mirrors 40 on neighboring chips 60 for reflecting light emitted from the etched facet 37 of a neighboring chip 60. However, in the layout shown in FIG. 5, each chip 60 also includes an optical detector 70 for detecting light emitted from the etched facet 36 of the neighboring chip 60. Each chip 60 has an additional etched facet 71 that is adjacent to the etched facet 36 of a neighboring chip 60. The etched facet 37 that faces a turning mirror 40 of a neighboring chip is typically coated with an AR coating (not shown). The etched facet 36 that faces the optical detector 70 of a neighboring chip is typically coated with an HR coating (not shown).

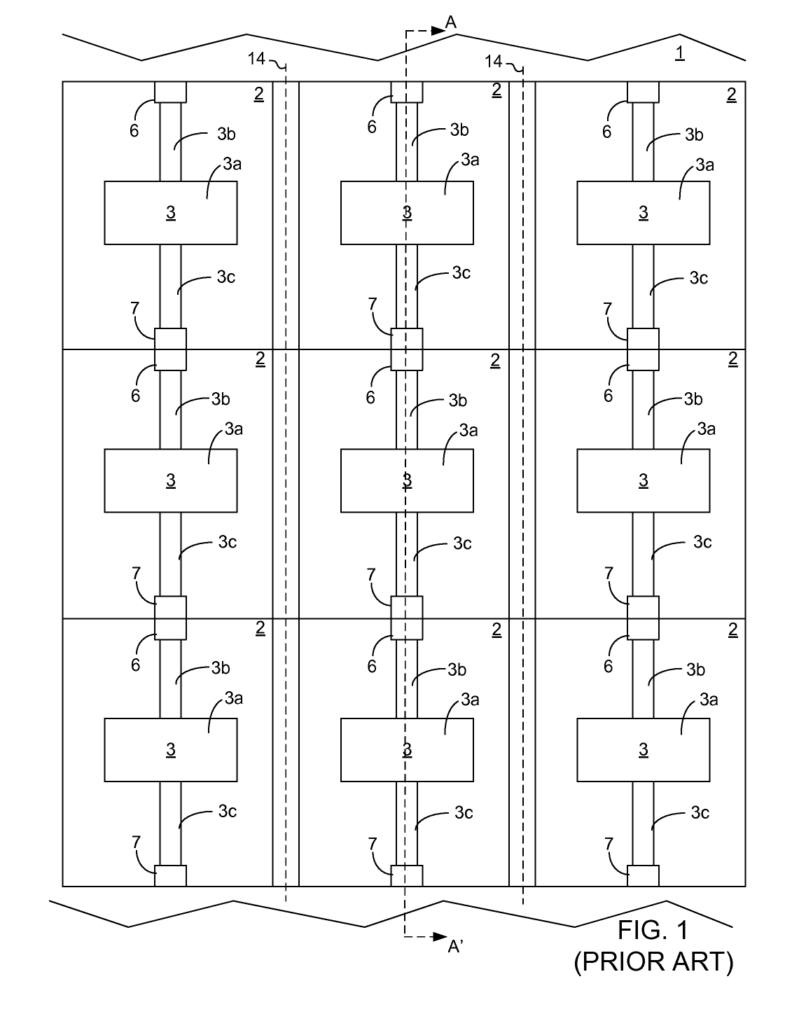

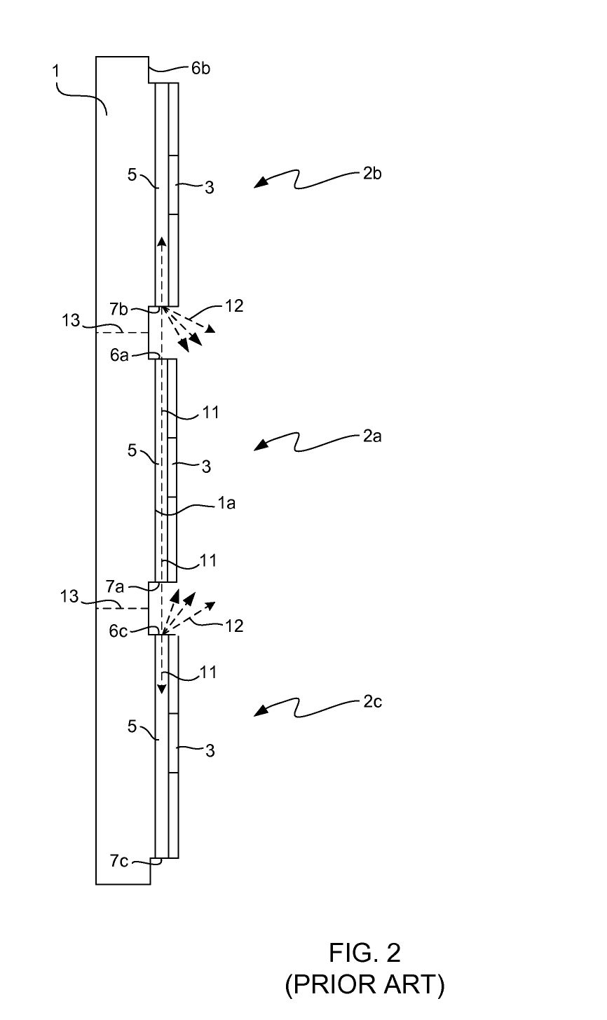

Each optical detector 70 includes an active region 72 and a metal probe pad 74. The active regions 72 receive light passing out of the etched facets 36 of neighboring chips 60 through etched facets 71 and convert the received light into an electrical current signal. A test probe (not shown) of external test and measurement equipment (not shown) may be placed in contact with the metal probe pads 74 to measure the electrical current signal generated by the optical detectors 70. Based on this measurement, processing circuitry of the test and measurement equipment can determine the optical power emitted through the typically HR-coated back facets of the neighboring chips 60. The manner in which the electrical current generated by an optical detector can be measured and processed to determine the optical power generated by a laser chip is known, as indicated above with reference to FIGS. 1 and 2.

With reference to FIG. 6, the manner in which the light generated by a given chip 60 is directed out of the wafer 50 at a non-zero-degree angle will now be described with reference to one of the chips 60. For exemplary purposes, it will be assumed that the center chip 60a on the drawing page is the DUT. The laser light 41 produced by the active region 35a of the center chip 60a travels in a direction that is parallel to the X-axis of the X, Y, Z Cartesian Coordinate system shown in the drawing page. The laser light 41 passes out of etched facets 36a and 37a. The directions of travel of the laser light represented by arrow 41 correspond to the optical axis of the center chip 60a. Light that passes out of etched facet 37a is incident on turning mirror 40c. The turning mirror 40c turns, or reflects, the light 41 by an angle of 90° relative to a plane in which the surface 50a of the wafer 50 lies away from the wafer 50. The direction of the reflected light is parallel to the Y-axis of the Cartesian Coordinate system and perpendicular to the X and Z-axes of the Cartesian Coordinate system. Optical detectors (not shown) may be positioned external to the wafer 50 to receive and process the reflected light 42 to obtain SMSR measurements. Wavelength and optical power measurements can also be obtained by processing the reflected light.

The light that passes out of etched facet 36a of chip 60a passes through etched facet 71b of chip 60b and is incident on the active region 72b of optical detector 70b of chip 60b. The optical detector 70b produces an electrical current in response to the received light. This electrical current can be measured using external test and measurement equipment (not shown) by placing a probe of the equipment in contact with the metal probe pad 74b. Based on this measurement, processing circuitry of the test and measurement equipment can determine the optical power of the light passing out of facet 36a of chip 60a. This process can be performed for all of the chips 60 on the wafer 50 prior to the wafer 50 being diced.

A variety of other tests may also be performed on the chips 60 prior to the wafer 50 being diced. After the laser chips 60 have been tested, the wafer 50 is diced. The dashed lines 56 in FIG. 6 represent the boundaries along which the wafer 50 is diced. The wafer 50 will also be diced along streets 55 (FIG. 5). As indicated above, after the wafer 50 is diced, each chip 60 has an optical detector 70 and a mirror 40 on it, but these elements are offset from the etched facets 36 and 37, respectively, in the Z-direction. For example, with reference to center chip 60a in FIG. 5, mirror 40a is offset in the Z-direction from the etched facet 37a. Therefore, the mirrors 40 that remain on the chips 60 do not detrimentally impact the chips 60 in any way. With reference to chip 60b, it can be seen that the optical detector 70b that was used to test light from chip 60a is located on chip 60b and that the optical detector 70b is offset in the Z-direction from the etched facet 36b. Therefore, the optical detectors 70 do not impact the performance of the chips 60 and may be considered throw-away elements.

It should be noted that although FIGS. 4 and 6 depict 45° mirrors 40 that reflect the light at 90° angles relative to the wafer surfaces 20a and 50a, the mirrors 40 could be made to have any desired angle and reflect light at any desired angle. Also, it is not necessary for all of the mirrors to have the same angle. The angle is chosen in part based on the ease with which optical detectors of test equipment external to the wafer can be positioned to receive the light reflected by the mirrors. To maximize distance between beams reflected by neighboring chips, it may be desirable for half of the mirrors to reflect light at a first angle and half of the mirrors to reflect light at a second angle that is different from the first angle. The manner in which the mirrors may be formed on the wafers to achieve a desired angle of reflection will now be described with reference to illustrative embodiments.

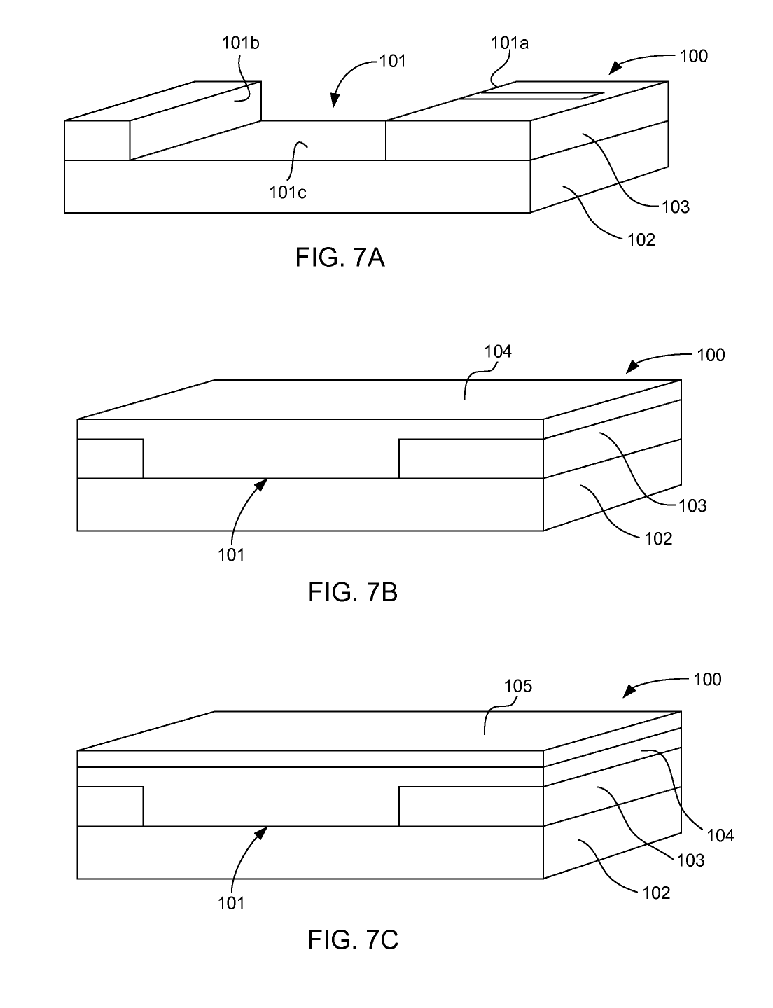

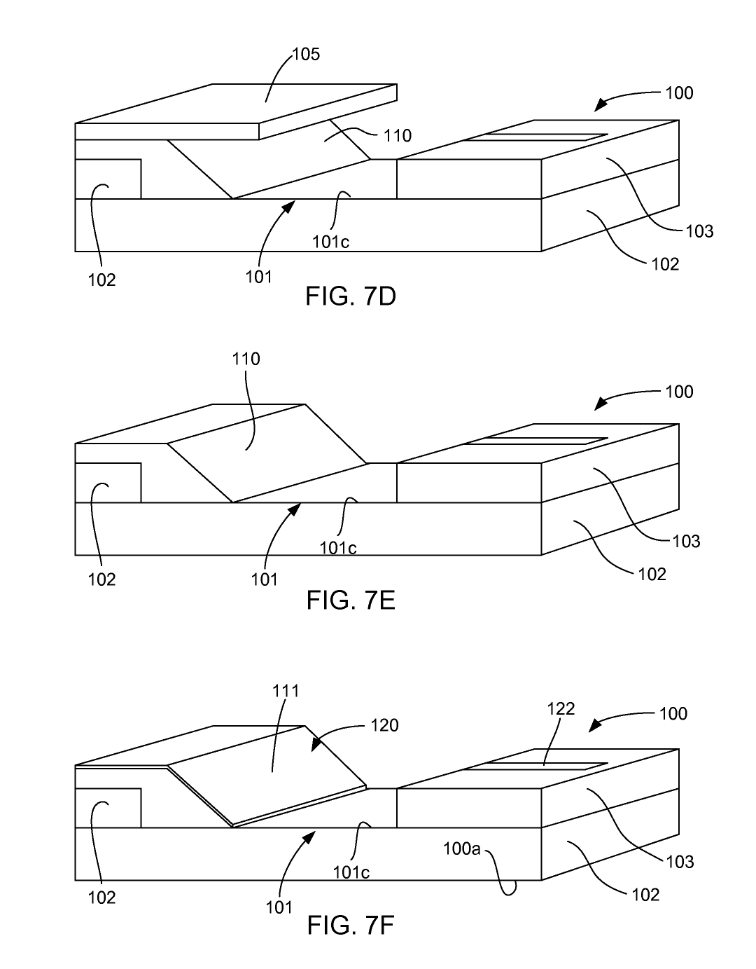

FIGS. 7A-7E illustrate the process steps for forming the turning mirrors on the wafers in accordance with an illustrative embodiment. FIG. 7A illustrates a cross-sectional perspective view of a portion of a semiconductor wafer 100 having an etched facet pit 101 formed therein. The wafer 100 has a substrate 102 on which multiple layers of semiconductor materials 103 have been formed and processed to create the laser chips 30 (FIGS. 3 and 4) and 60 (FIGS. 5 and 6). The etched facet pit 101 has vertical side walls 101a and 101b that oppose one another and a bottom surface 101c. For illustrative purposes, the bottom surface 101c is shown as being flat and perpendicular to the side walls 101a and 101b, but it may have other shapes, as indicated above. Likewise, the side walls 101a and 101b are shown as being flat, vertical and precisely parallel to one another for illustrative purposes, but this is not necessarily the case.

FIG. 7B illustrates a cross-sectional perspective view of the portion of the semiconductor wafer 100 shown in FIG. 7A after a layer of polymer material 104 has been deposited on top of the semiconductor layers 103. The polymer material fills the etched facet pit 101. One suitable polymer material is Pro-Lift™ 100-24 polyetherimide (PI) manufactured by Brewer Science of Rolla, Mo. After the polymer material 104 has been deposited, the wafer 100 is baked at a preselected temperature for a preselected period of time to cure the polymer material 104 and make it insoluble in acetone. For example, assuming Pro-Lift™ 100-24 PI is used for this purpose, a bake temperature of 260° Celsius (C) for 5 minutes is sufficient.

FIG. 7C illustrates a cross-sectional perspective view of the portion of the semiconductor wafer 100 shown in FIG. 7B after a layer of photoresist 105 has been formed on top of the layer of polymer material 104. A suitable photoresist material for this purpose is SPR™ 220 photoresist material manufactured by The Dow Chemical Company of Midland, Mich.

FIG. 7D illustrates a cross-sectional perspective view of the portion of the semiconductor wafer 100 shown in FIG. 7C after (1) the layer of photoresist 105 has been applied and baked using a standard bake temperature and time period; (2) the layer of photoresist 105 has been patterned into a desired mask via a photolithographic process and (3) the patterned layer of photoresist 105 and the layer of polymer material 104 have been developed using a desired developer agent that will dissolve both the photoresist and the polymer material. Because the polymer material is soluble in the developer agent, an angled surface 110 is formed that has a preselected angle relative to the wafer surface 50a. The preselected angle depends on the bake temperature and time used in the process step described above with reference to FIG. 7B and the extent of over-development that occurs using the developer agent during the process step described above with reference to FIG. 7D. By adjusting these process conditions appropriately, a preselected angle of a desired value can be obtained.

For example, assuming SPR™ 220 photoresist is used as the photoresist material for layer 105 and that the mirror is intended to be a 45° mirror, step (2) may comprise patterning SPR™ 220 photoresist layer 105 into a desired pattern using typical photolithographic techniques, and step (3) may comprise developing the patterned layer 105 and the unmasked portions of layer 104 in a developer material such as AZ 300 metal-ion-free (MIF) positive photoresist developer for a period of 7 to 8 minutes. AZ 300 MIF positive photoresist developer is manufactured by AZ Electronic Materials USA Corporation, which is a subsidiary of Merck KGaA of Darmstadt, Germany.

The preselected angle typically ranges from about 25° to about 50° relative to the wafer surface 100a. Some experimentation may be needed to select an appropriate developer and bake time and temperature to be used to achieve a desired angle. Through experimentation, persons of skill in the art will be able to readily determine the process conditions that are needed to achieve the desired angle.

FIG. 7E illustrates a cross-sectional perspective view of the portion of the semiconductor wafer 100 shown in FIG. 7D after a chemical etch process that uses acetone is performed to remove the layer of photoresist 105.

FIG. 7F illustrates a cross-sectional perspective view of the portion of the semiconductor wafer 100 shown in FIG. 7E after a reflective surface 111 has been formed on the angled surface 110. The reflective surface 111 may be a dielectric mirror or a metal mirror. The manner in which dielectric and metal mirrors can be formed on a wafer is known and therefore will not be described in further detail. The combination of the reflective surface 111 and the angled surface 110 forms a turning mirror 120. The spatial relationship between the turning mirror 120 and an edge-emitting laser 122 is shown in FIG. 7F. In this illustrative embodiment, the angle of the turning mirror 120 relative to the lower wafer surface 100a is 45°, which causes the light emitted from the laser 122 to be turned by an angle of 90° relative to the lower wafer surface 100a.

Although the process of using the polymer material 104 to form the angled surface 110 and placing a reflective surface 111 on the angled surface 110 is suitable for this purpose, other processes may be used for this purpose. For example, the angled surface may be formed in various materials using various processes, including, for example, plasma etching, wet etching, dry etching, or photolithography. All of these processes are controllable to achieve an angled surface having a desired angle in a selected material. Therefore, the method of forming the turning mirrors on the wafers is not limited to the method described above with reference to FIGS. 7A-7F.

In the above description, terms such as “vertical,” “horizontal,” “flat,” and “angled” have been used to describe shapes and orientations of features formed in the wafers. It should be kept in mind that these and other terms used herein to describe the shapes, directions or orientations of features are intended to denote general shapes, directions or orientations, or the intended shapes, directions or orientations of features that are achievable within tolerances for the processes and/or materials that are used to form them, as will be understood by persons of skill in the art. For example, vertical walls formed using semiconductor fabrication processes may not be perfectly vertical because of imperfections or tolerance variations in the processes and/or materials used to make them. Therefore, the term “vertical,” as that term is used herein, is intended to mean substantially, or generally, vertical. The same is true for other terms used herein to denote shapes, directions or orientations of features.

It should be noted that the invention has been described with reference to illustrative embodiments for the purposes of demonstrating the principles and concepts of the invention. The invention, however, is not limited to these examples, as will be understood by persons of skill in the art in view of the description being provided herein. Many modifications may be made to the embodiments described while still achieving the goal of the invention. For example, although the illustrative embodiments have been described with reference to a particular angle for the turning mirrors for directing light out of the wafer in a particular direction, other angles for the turning mirror and for the direction of light are possible, as will be understood by persons of skill in the art. Also, processes other than those described herein may be used to form the turning mirrors on the wafers. Persons of skill in the art will understand that these and other modifications may be made and that all such modifications are within the scope of the invention.

What is claimed is:

1. A semiconductor wafer comprising:
a plurality of edge-emitting laser chips having respective edge-emitting lasers that emit laser light from facets formed in edges of the chips; and
a plurality of turning mirrors disposed on the wafer, each turning mirror receiving laser light emitted from one of the chips and turning the received laser light away from the wafer at a non-zero-degree angle relative to a plane in which one of an upper surface and a lower surface of the wafer lies.

2. A semiconductor wafer comprising:
a plurality of edge-emitting laser chips, each chip sharing a boundary on the wafer with at least one adjacent edge-emitting laser chip and each chip having an optical axis, wherein at least a first portion of laser light produced by a respective laser of each respective chip travels along the respective optical axis of the chip and is emitted from the respective chip through a first facet of the respective chip; and
a plurality of first turning mirrors disposed on the wafer, each first turning mirror being positioned and angled to receive the respective first portion of laser light passing through the respective first facet of the respective chip and to turn the received first portion of laser light by a first predetermined turning angle relative to a plane in which one of an upper and a lower surface of the wafer lies in a direction away from the wafer.

3. The semiconductor wafer of claim 2, wherein each first turning mirror is located in a facet pit of a chip that is adjacent to the chip that emitted the first portion of laser light that is turned by the respective first turning mirror.

4. The semiconductor wafer of claim 3, wherein each first predetermined turning angle is greater than or equal to 30 degrees.

5. The semiconductor wafer of claim 4, wherein at least one of the first predetermined turning angles is different from at least one other first predetermined angle.

6. The semiconductor wafer of claim 3, wherein the first predetermined turning angle is less than or equal to 150 degrees.

7. The semiconductor wafer of claim 2, wherein the first predetermined turning angle is about 90 degrees.

8. The semiconductor wafer of claim 3, wherein at least a second portion of laser light produced by each respective laser of each respective chip travels along the respective optical axis and is emitted from the respective chip through a second facet of the respective chip, and wherein facets of adjacent chips are staggered from one another on the wafer so that the facets that share a boundary between adjacent chips are offset from one another.

9. The semiconductor wafer of claim 8, further comprising:
a plurality of first optical detectors disposed on the wafer, each of the first optical detectors being positioned to receive one of the respective second portions of the laser light passing through the second facet of a respective chip and to convert the received laser light into an electrical signal.

10. The semiconductor wafer of claim 9, wherein each first optical detector is located in a facet pit of a chip that is adjacent to the chip that emitted the second portion of the laser light that is converted by the respective first optical detector into an electrical signal.

11. The semiconductor wafer of claim 8, further comprising:
a plurality of second turning mirrors disposed on the wafer, each second turning mirror being positioned and angled to receive one of the respective second portions of the laser light passing through the second facet of the respective chip and to turn the received second portion of the laser light by a second predetermined turning angle relative to the plane in which one of the upper and lower surfaces of the wafer lies in a direction away from the wafer.

12. The semiconductor wafer of claim 11, wherein the first and second predetermined angles are equal to one another such that the first and second turning mirrors turn the laser light received thereby by a same angle relative to the plane in which one of the upper and lower surfaces of the wafer lies.

13. The semiconductor wafer of claim 11, wherein the first and second predetermined angles are different from one another such that the first and second turning mirrors turn the laser light received thereby by different angles relative to the plane in which one of the upper and lower surfaces of the wafer lies.

14. The semiconductor wafer of claim 11, wherein at least one of the first predetermined angles is different from at least one other first predetermined angle.

15. The semiconductor wafer of claim 11, wherein at least one of the second predetermined angles is different from at least one other second predetermined angle.

16. The semiconductor wafer of claim 11, wherein the first and second turning mirrors are 45-degree turning mirrors.

17. A method for measuring characteristics of laser light emitted by edge-emitting laser chips of a semiconductor wafer, the method comprising:
with turning mirrors positioned on the wafer to receive first portions of laser light emitted by edge-emitting lasers of the chips through first facets formed in edges of the chips, turning the respective first portions of the laser light away from the wafer at a non-zero-degree angle to a plane in which one of the upper and lower surface of the wafer lies; and
with a first measurement device, measuring at least one of the turned first portions of laser light and determining one or more characteristics of the measured laser light.

18. The method of claim 17, wherein said one or more characteristics include optical power.

19. The method of claim 17, wherein said one or more characteristics include wavelength.

20. The method of claim 17, wherein said one or more characteristics include side-mode suppression ratio.

21. The method of claim 17, further comprising:
with optical detectors positioned on the wafer to detect at least portions of the laser light emitted by the edge-emitting lasers of the chips through second facets formed in edges of the chips, receiving respective second portions of the laser light emitted from the respective edge-emitting lasers of the respective chips and converting the received portions into respective electrical signals; and
with a second measurement device, measuring at least one of the electrical signals and determining one or more characteristics of the detected laser light based on the measured electrical signal.

22. The method of claim 21, wherein said one or more characteristics determined by the first measurement device include side-mode suppression ratio and wherein said one or more characteristics determined by the second measurement device include optical power.

23. The method of claim 22, wherein said one or more characteristics determined by the first measurement device include wavelength.

24. The method of claim 22, wherein said one or more characteristics determined by the first measurement device include optical power.

25. A method of forming a plurality of turning mirrors on a semiconductor wafer, the wafer having a plurality of edge-emitting laser chips formed thereon, each chip having a respective edge-emitting laser that emits laser light in at least a first direction that is parallel to a plane in which one of a top and a bottom surface of the wafer lies, the method comprising:
forming a plurality of turning mirrors on the wafer, each turning mirror being formed at a position on the wafer that allows the turning mirror to receive laser light emitted by one of the chips, each turning mirror having a reflecting surface that is at a predetermined angle relative to an optical axis of the respective chip for turning received laser light away from the wafer at a non-zero-degree angle relative to said plane.

26. The method of claim 25, wherein the forming step comprises:
disposing a polymer material on the wafer such that the polymer material fills in at least one facet pit of each of the chips, each facet pit being defined by first and second side walls and a bottom surface;
curing the polymer material to harden the polymer material;
performing a controlled etch of the cured polymer material to form angled surfaces in the cured polymer material against the first side walls of the respective facet pits; and
forming reflectors on the angled surfaces to create the turning mirrors.

27. The method of claim 26, further comprising:
prior to performing the controlled etch, depositing a layer of photoresist on top of the cured polymer layer; and
forming a patterned photoresist mask in the photoresist layer.

28. The method of claim 27, wherein the step of performing the controlled etch comprises:
subjecting the photoresist mask and the cured polymer material to a developer agent in which the photoresist mask and the cured polymer material are soluble for a predetermined length of time during which time the angled surfaces are formed in the cured polymer material.

29. The method of claim 28, wherein the step of forming the reflectors comprises:
removing the developed photoresist to expose the angled surfaces; and
forming either dielectric mirrors or metal mirrors on the angled surfaces.

30. The method of claim 26, wherein the step of curing the polymer material comprises baking the wafer at a predetermined temperature for a predetermined period of time.
